(19) United States
(12) Patent Application Publication
(10) Pub. No.: US 2023/0126835 A1
(43) Pub. Date: Apr. 27, 2023

(54) ANTIMICROBIAL SHEET AND MANUFACTURING METHOD THEREOF

(71) Applicants: UACJ Corporation, Tokyo (JP); UACJ Foil Corporation, Tokyo (JP)

(72) Inventors: Atsushi KOISHIKAWA, Aichi (JP); Takahiro NISHIJIMA, Kyoto (JP)

(21) Appl. No.: 17/915,532

(22) PCT Filed: Apr. 2, 2021
(86) PCT No.: PCT/JP2021/014269

§ 371 Date: Sep. 29, 2022

(30) Foreign Application Priority Data
Apr. 9, 2020 (JP) 2020-070621

(51) Int. Cl. B32B 15/08; B32B 15/20; C23C 14/08

(52) U.S. Cl. CPC B32B 15/08; B32B 15/20; C23C 14/087; B32B 2270/00; B32B 2311/12; B32B 2323/04; B32B 2307/7145

(57) ABSTRACT

An antimicrobial sheet may have a copper film formed on at least one side of a resin or polymer film. The copper film contains one or more copper oxides and a non-oxide copper. The content of the non-oxide copper in the copper film is less than the content of the copper that forms the copper oxide(s) and is 0.04 g/m² or less.

### TECHNICAL FIELD

The present invention relates to an antimicrobial sheet and to a manufacturing method thereof.

### BACKGROUND ART

In recent years, the use of electronic devices, such as personal computers, has been advancing in medical-treatment facilities, food-processing facilities, and the like. In medical-treatment facilities and the like, there is demand to inhibit the propagation of harmful microorganisms, such as pathogens, indoors and to maintain indoor cleanliness. In the past, indoor cleanliness was maintained in these types of facilities by various methods such as cleaning by wiping with water, microbe elimination using a pharmaceutical agent, and the like. To maintain indoor cleanliness by methods such as cleaning, microbe elimination, or the like, it is necessary to periodically perform cleaning, microbe elimination, or the like.

However, because the interfaces of electronic devices, such as keyboards, operation panels, touch panels, and the like, are frequently touched by numerous people, cleanliness tends to be impaired. To maintain the cleanliness of these parts, ideally it is preferable to perform cleaning, microbe elimination, or the like at every use; however, to perform cleaning or the like at every use is extremely onerous. Consequently, there is demand to reduce the frequency of cleaning, microbe elimination, and the like.

With respect to these problems, methods are gaining attention in which the frequency of cleaning, microbe elimination, and the like is reduced by covering the interface with a sheet, a film, or the like having an antimicrobial effect, that is, having an effect that inhibits propagation of microbes. For example, in Patent Document 1, an antimicrobial film is described in which at least one layer of an antimicrobial, metallic thin film is formed on at least one surface of a flexible polymer film substrate, and the metallic thin film is composed of a vapor-deposited film that is formed by a vacuum vapor-deposition method performed by thermally melting a metallic evaporation source.

### PRIOR ART LITERATURE

### Patent Documents

Patent Document 1
Japanese Laid-open Patent Publication 2010-247450

### SUMMARY OF THE INVENTION

### Problem to be Solved by the Invention

When using an antimicrobial film on a display object, such as an interface, a printed object, or the like, there is demand for light transmittance (transmittance of visible light) to the extent that the display contents thereof can be easily differentiated; however, because the extent of light transmittance required differs according to the display mode, the usage environment, and the like of the display object, there is demand for the ability to easily adjust the light transmittance of the antimicrobial film. Nevertheless, in the configuration disclosed in Patent Document 1, the adjustment of the light transmittance cannot be performed easily while maintaining the antimicrobial action of the antimicrobial film, and therefore there is room for improvement.

The present invention was conceived considering this background, and an object of the present invention is to provide an antimicrobial sheet in which light transmittance can be easily adjusted.

### Means for Solving the Problem

One aspect of the present invention is an antimicrobial sheet comprising:

a resin film; and

a copper film, which is formed on at least one side of the resin film and contains a copper oxide or copper oxides and a non-oxide copper;

wherein the content of the non-oxide copper in the copper film is less than the content of the copper that forms the copper oxide(s) and is 0.04 g/m² or less.

### Effects of the Invention

According to the above-mentioned antimicrobial sheet, the content of the non-oxide copper in the above-mentioned copper film is 0.04 g/m² or less. In the above-mentioned range, there is a correlation between the content of the non-oxide copper in the above-mentioned copper film and the light transmittance of the antimicrobial sheet and, in the area in which the amount of the non-oxide copper is small, there is a tendency for the light transmittance to change greatly relative to change in the amount of non-oxide copper. Consequently, by adjusting the content of the non-oxide copper to be within the above-mentioned range, the light transmittance can be easily adjusted while maintaining the light transmittance to the extent that the display contents thereof can be easily differentiated when the antimicrobial sheet is used on a display object.

Furthermore, because the above-mentioned copper film is composed of the copper oxide(s) and the non-oxide copper, the antimicrobial sheet exhibits a copper color or brass color. Furthermore, by adjusting the non-oxide copper included in the above-mentioned copper film to within the range of 0.04 g/m² or less, the intensity of the hue of the copper color can be adjusted. For example, by setting the antimicrobial sheet to a state that is suitably tinged with a copper color, it becomes easy to recognize that the antimicrobial sheet is a sheet having an antimicrobial effect; consequently, it is also possible to obtain a sense of security that the propagation of microbes is inhibited on the part where the antimicrobial sheet is provided.

According to the present invention as described above, it is possible to provide an antimicrobial sheet in which light transmittance can be easily adjusted.

### BRIEF DESCRIPTION OF THE DRAWINGS

FIG. 1 is a graph that shows the analysis results of O 1s spectra generated by XPS according to working examples.

FIG. 2 is a graph that shows the analysis results of Cu 2p spectra generated by XPS according to the working examples.

FIG. 3 is a graph that shows the analysis results of Cu LMM spectra generated by XPS according to the working examples.

FIG. 4 is a conceptual diagram that shows the abundance ratios of Cu and Cu₂O based on chemical bonding states according to the working examples.

FIG. 5 is a chart that shows the relationship between the amount of non-oxide copper and the amount of drop in light transmittance according to the working examples.

FIG. 6 includes, according to working examples: (a) a photograph, substituting for a drawing, that shows an overlapped state between Test Body B4 and a printed object; and (b) a photograph, substituting for a drawing, that shows an overlapped state between Test Body A6 and the printed object.

### MODES FOR CARRYING OUT THE INVENTION

The above-mentioned copper film is preferably composed of a sputtered film that includes the above-mentioned copper oxide(s) and the above-mentioned non-oxide copper. Because the copper film can be made more finely in this situation than in the situation in which the copper film is composed of a vapor-deposited film, the film thickness can be made thin without reducing the copper content. Furthermore, because a thin film composed of the copper oxide(s) transmits visible light, particularly long-wavelength light, it has high transmittance. As a result, light transmittance can be increased while maintaining the antimicrobial effect. In addition, a copper film containing the non-oxide copper in a desired amount can be easily formed.

The sum total of the content of the copper that forms the above-mentioned copper oxide(s) and the content of the above-mentioned non-oxide copper preferably is 0.04 g/m² or more. In this situation, because the copper film formed on the resin film exhibits a sufficient antimicrobial effect, the antimicrobial effect of the antimicrobial sheet can be ensured.

In the above-mentioned antimicrobial sheet, a resin film that is transparent to visible light can be used as the resin film. The resin film preferably contains one or two or more resins from among polyester, polyolefin, polycarbonate, polyurethane, polyvinyl chloride, and silicone. Each of these resins has a high refractive index and has a refractive index that is higher than that of a copper film containing the copper oxide(s). Consequently, by using a film that contains these resins as the resin film, the interface reflectance of the copper film containing the copper oxide(s) can be reduced, and thereby the visible-light transmittance of the antimicrobial sheet can be further increased. In addition, because each of these resins has high heat resistance, deterioration of the resin film when sputtering is performed in the process of manufacturing the antimicrobial sheet can be curtailed.

For example, polyethylene terephthalate, polymethylene terephthalate, polybutylene terephthalate, polyethylene naphthalate, polybutylene naphthalate, or the like can be used as the polyester. In addition, for example, an olefin homopolymer, such as polyethylene, polypropylene, or the like, or an olefin-containing copolymer, such as an ethylene-propylene copolymer, can be used as the polyolefin.

The thickness of the resin film can be set to, for example, 5-250 μm. In the situation in which the thickness of the resin film is less than 5 μm, handling of the resin film in the manufacturing process tends to become difficult. On the other hand, in the situation in which the thickness of the resin film is greater than 250 μm, there is a risk that it will lead to a decrease in the transmittance of visible light.

The antimicrobial sheet may have an undercoat (AC) layer between the resin film and the copper film. In this situation, the adhesive properties between the resin film and the copper film can be further improved, and thereby peeling of the copper film from the resin film can be curtailed for a longer time. As a result, the antimicrobial efficacy of the above-mentioned antimicrobial sheet can be maintained for a longer time.

For example, a resin-coating agent having high adhesive properties for both the resin film and copper oxide can be used as the undercoat layer. As examples of such a resin-coating agent, there are, for example, resin-coating agents that contain a resin, such as polyamide-based resins, polyolefin-based resins, epoxy-based resins, polyester-based resins, polyurethane-based resins, acrylic-based resins, nitrocellulose-based resins, and the like.

In addition, an adhesive layer for fixing the antimicrobial sheet to the target object to be protected may be provided on the rear surface of the resin film of the above-mentioned antimicrobial sheet, that is, on the surface of the antimicrobial sheet on the side that does not have the copper film. The material of the adhesive layer is not particularly limited, as long as it is transparent. For example, an acrylic-based adhesive agent, a rubber-based adhesive agent, a urethane-based adhesive agent, a silicone-based adhesive agent, or the like can be used as the adhesive layer. It is noted that, in the situation in which an adhesive layer is provided, the adhesive layer may be protected, and a separator film, which can be easily peeled off when the antimicrobial sheet is to be affixed to the target object, may be laminated on the adhesive layer. In this situation, handling of the antimicrobial sheet having the adhesive layer becomes easy, and thus ease of use is improved. The separator film should be a material that is easily peelable from the adhesive layer; for example, it is possible to use one in which a peeling layer composed of a silicone-based adhesive agent or the like is provided on a substrate composed of a polyester resin, a polyolefin resin, or the like.

As the above-mentioned antimicrobial-sheet manufacturing method, a method can be used in which, for example, the above-mentioned copper film is formed on the above-mentioned resin film by sputtering, in a gas-mixture atmosphere that contains an inert gas and oxygen gas, while controlling the amount of oxygen gas that is introduced. Using such a manufacturing method, a copper film composed of a sputtered film containing the copper oxide(s) and the non-oxide copper can be formed on the resin film. Furthermore, the content of the non-oxide copper is set to 0.04 g/m² or less by adjusting the ratio of the copper oxide(s) and the non-oxide copper in the copper film in accordance with the amount of oxygen gas that is introduced into a gas mixture.

In the above-mentioned manufacturing method, after the resin film is prepared and before sputtering is performed, the resin film may be pretreated as needed. As the pretreatment, for example, a treatment for normalizing the surface of the resin film can be performed. Specifically, a surface treatment, such as a corona-discharge process, a plasma process, a glow-discharge process, or the like, can be utilized as such a treatment.

### Working Examples

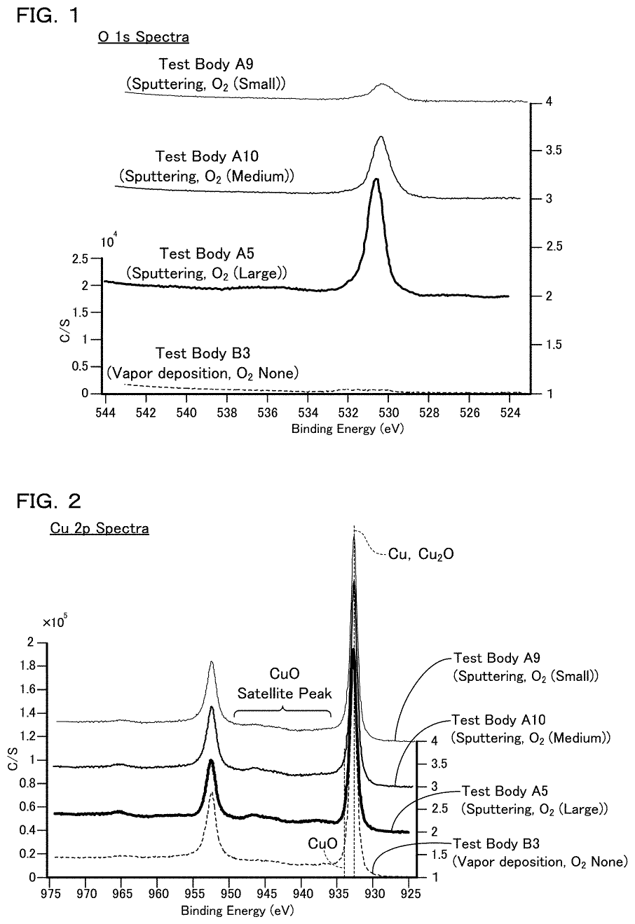

Working examples of the above-mentioned antimicrobial sheet and a manufacturing method thereof will be explained, with reference to FIG. 1 to FIG. 6. It is noted that the specific aspects of the antimicrobial sheet and the manufacturing method thereof according to the present invention are not limited to the aspects below, and the composition(s) can be modified where appropriate within a range that does not depart from the gist of the present invention.

The antimicrobial sheets of the present examples comprise a resin film and a copper film, which is formed on at least one side of the resin film. The copper film contains a copper oxide or copper oxides and a non-oxide copper. Furthermore, the content of the non-oxide copper in the copper film is less than the content of the copper that forms the copper oxide(s) and is 0.04 g/m² or less, may be 0.03 g/m² or less, and preferably is 0.02 g/m² or less.

Although it is uncertain how copper particles and copper oxide particles exist in the above-mentioned copper film, it is conjectured that oxidized copper particles, partially oxidized copper particles, and non-oxidized copper particles are mixed in. It is noted that it is assumed that the copper oxide(s) in the copper film do(es) not contain anything resulting from natural oxidation or unavoidable impurities. It is noted that the copper particles may be composed of pure copper and may be composed of copper alloys. In the situation in which the copper particles are composed of a copper alloy, from the viewpoint of sufficiently exhibiting antimicrobial efficacy due to the copper, the copper content in the copper alloy is preferably 60 mass % or more.

The ratio of the content of copper that forms the copper oxide(s) relative to the amount of Cu in the copper film (the sum total of the content of the copper that forms the copper oxide(s) and the content of the non-oxide copper) is 40% or more, can be set to, for example, 85% or more, and preferably is 90% or more.

Antimicrobial sheets of the present examples are described in detail below. It is noted that Test Bodies A2-A7, A12-A18 shown in Table 1 below were prepared as test bodies of the antimicrobial sheets of the present examples. In addition, Test Bodies A1, A8-A11, B1-B8 shown in Table 1 below were prepared as sheets for comparative examples.

Each test body can be manufactured by using the following method.

First, resin films were prepared. As the resin films, as shown in the “Substrate” column in Table 1 below, transparent films containing polyethylene terephthalate and having a thickness of 50 μm were prepared for Test Bodies A1-A10 and B1-B8, transparent films containing urethane and having a thickness of 50 μm were prepared for Test Bodies A11-A17, and a transparent film containing polyethylene and having a thickness 25 μm was prepared for Test Body A18.

Furthermore, with regard to each of Test Bodies A2-A10, A12-A18, and B1-B8, a copper film was formed on one side of the resin film. With regard to each of Test Bodies A2-A10 and A12-A18, a copper film, which was composed of a sputtered film containing copper oxide(s) and non-oxide copper, was formed by sputtering. As the sputtering gas used in sputtering, it was possible to use a gas mixture in which oxygen (O₂) was added in a range of 10-50% to pure argon (Ar having a purity of 99.999%). Sputtering was performed by magnetron sputtering in which the degree of vacuum was set to 0.12 Pa. It is noted that, as the target in the sputtering, it was possible to use oxygen-free copper having a purity of 99.9 mass % or more. It is noted that, with regard to each of Test Bodies A1 and A11, sputtering was not performed, and thus a copper film was not formed on the resin film.

The above-mentioned sputtering could be performed, for example, as follows. First, the resin film was placed on a cooling roll in the sputtering apparatus. Subsequently, the interior of the sputtering apparatus was depressurized using a vacuum pump, and Ar gas or a gas mixture of Ar and O₂ was introduced. Furthermore, sputtering was performed while cooling the resin film using the cooling roll. Thus, by performing sputtering while cooling the resin film, the occurrence of thermal contraction, wrinkles, strain, and the like of the resin film could be curtailed.

The amount of oxygen introduced in the above-mentioned sputtering apparatus was set to four steps—“Large,” “Medium,” “Small,” and “None”—as shown in the “Amount of Oxygen Introduced” column in Table 1 below. Furthermore, sputtering was performed by controlling the amount of oxygen that was introduced to within the ranges shown in Table 1 and by modifying the sputtering speed and the film formation time as appropriate; thereby, the antimicrobial sheets shown in Table 1 (Test Bodies A1-A18) were obtained. The set values of the film thicknesses of the copper films during sputtering were as recorded in the “Target Film Thickness” column in Table 1.

TABLE 1

| | | | | | | | | Amount | |
|---|---|---|---|---|---|---|---|---|---|
| Test | | | Film | Amount of | Target Film | XRF Film | Amount | of Non- | CuO + |
| Body | Substrate | | Forming | Oxygen | Thickness | Thickness | of Cu | Oxide Copper | Cu₂O |
| Symbol | Type | Thickness | Method | Introduced | (nm) | (nm) | (g/m²) | (g/m²) | Ratio |
| A1 | PET | 50 μm | — | — | — | 0 | 0 | 0 | — |
| A2 | | | Sputtering | Large | 5 | 5 | 0.04 | 0.004 | 0.91 |
| A3 | | | | Large | 10 | 10 | 0.10 | 0.01 | |
| A4 | | | | Large | 15 | 19 | 0.19 | 0.01 | 0.93 |
| A5 | | | | Large | 20 | 26 | 0.23 | 0.02 | 0.90 |
| A6 | | | | Large | 25 | 32 | 0.29 | 0.01 | 0.95 |
| A7 | | | | Large | 30 | 34 | 0.32 | 0.02 | |
| A8 | | | | None | 20 | 20 | 0.19 | 0.18 | 0.04 |
| A9 | | | | Small | 20 | 25 | 0.22 | 0.19 | 0.14 |
| A10 | | | | Medium | 20 | 24 | 0.22 | 0.12 | 0.44 |
| A11 | Urethane | 50 μm | — | — | 0 | 0 | 0 | 0.00 | |
| A12 | | | Sputtering | Large | 5 | 5 | 0.04 | 0.003 | |
| A13 | | | | Large | 10 | 10 | 0.09 | 0.01 | |
| A14 | | | | Large | 15 | 14 | 0.14 | 0.01 | |
| A15 | | | | Large | 20 | 19 | 0.18 | 0.01 | |
| A16 | | | | Large | 25 | 25 | 0.24 | 0.02 | |
| A17 | | | | Large | 30 | 31 | 0.27 | 0.02 | |
| A18 | PE | 25 μm | Sputtering | Large | 20 | 22 | 0.20 | 0.01 | |
| B1 | PET | 50 μm | Vapor | None | 10 | 9 | 0.08 | 0.08 | |
| B2 | | | deposition | None | 15 | 13 | 0.12 | 0.12 | |
| B3 | | | | None | 20 | 18 | 0.16 | 0.15 | 0.04 |
| B4 | | | | None | 25 | 24 | 0.21 | 0.20 | |
| B5 | | | | None | 30 | 29 | 0.26 | 0.25 | |
| B6 | | | | Small | 30 | 29 | 0.27 | 0.26 | |
| B7 | | | | Medium | 30 | 30 | 0.31 | 0.30 | |
| B8 | | | | Large | 30 | 29 | 0.28 | 0.27 | |

| | | Amount of | | | Capacitance- | | |
|---|---|---|---|---|---|---|---|
| Test | Light | Drop in Light | | Surface | Type Touch | Antimicrobial-Activity Value | |
| Body | Transmittance | Transmittance | | Resistivity | Panel | Staphylococcus | Escherichia |
| Symbol | (%) | (%) | Visibility | (Ω/□) | Property | aureus | coli |
| A1 | 89 | 0 | A | O.L. | ◯ | — | — |
| A2 | 75 | 14 | A | O.L. | ◯ | | |
| A3 | 64 | 25 | A | O.L. | ◯ | | |
| A4 | 53 | 36 | A | O.L. | ◯ | | |
| A5 | 48 | 41 | A | O.L. | ◯ | | |
| A6 | 41 | 48 | A | O.L. | ◯ | | |
| A7 | 38 | 51 | A | O.L. | ◯ | | |
| A8 | 21 | 68 | B | 5.0 | X | | |
| A9 | 20 | 69 | C | 22 | X | | |
| A10 | 23 | 66 | B | 988 | ◯ | | |
| A11 | 90 | 0 | A | O.L. | ◯ | — | — |
| A12 | 78 | 12 | A | O.L. | ◯ | 4.3 | 6.1 |
| A13 | 64 | 27 | A | O.L. | ◯ | 4.3 | 6.1 |
| A14 | 56 | 34 | A | O.L. | ◯ | 4.3 | 6.1 |
| A15 | 48 | 42 | A | O.L. | ◯ | 4.3 | 6.1 |
| A16 | 44 | 47 | A | O.L. | ◯ | 4.3 | 6.1 |
| A17 | 42 | 48 | A | O.L. | ◯ | | |
| A18 | 46 | — | A | O.L. | ◯ | | |
| B1 | 53 | 36 | A | 19 | X | 3.6 | 0.5 |
| B2 | 42 | 47 | A | 8.1 | X | 4.3 | 6.1 |
| B3 | 32 | 57 | A | 4.9 | X | 4.3 | 6.1 |
| B4 | 23 | 67 | B | 2.1 | X | 4.3 | 6.1 |
| B5 | 16 | 73 | C | 7.1 | X | 4.3 | 6.1 |
| B6 | 15 | 74 | C | 8.2 | X | | |
| B7 | 12 | 77 | C | 12.1 | X | | |
| B8 | 11 | 78 | C | 12.5 | X | | |

In addition, with regard to each of Test Bodies B1-B8 as comparative examples, a copper film was formed on a resin film by a vacuum vapor-deposition method. Oxygen-free copper having a purity of 99.9 mass % or more was used as the vapor-deposition source.

The amount of copper oxide(s) and the amount of non-oxide copper in each of the test bodies were measured as follows.

First, the measurement of the amount of Cu (the total amount of the copper, which formed the copper oxide(s), and the non-oxide copper) in the copper film of each of the test bodies was performed using an atomic absorption spectral analysis method. In the above-mentioned atomic absorption spectral analysis, a polarized Zeeman atomic absorption spectrophotometer (ZA3000, made by Hitachi Hi-Tech Science Corporation) was used; each test body, on which a copper film was formed, was gently added into (1+1) hydrochloric acid to dissolve the Cu, and the amount of Cu, which is the mass of Cu, was measured using an atomic absorption spectrophotometer. The measurement results thereof were recorded in the “Amount of Cu” column in Table 1. In addition, an X-ray fluorescence analyzer (ZSX PrimusIV, made by Rigaku Corporation) was used to measure the X-ray fluorescence intensity of the Cu-Kα line at the surface on which the copper film was formed in each test body and to measure the Cu film thickness of each test body based on a calibration curve of known X-ray fluorescence intensities for Cu film thicknesses; the measurement results thereof were recorded in the “Cu Film Thickness (XRF)” column in Table 2 below.

The measurement of the abundance ratio of copper oxide(s) and non-oxide copper in the coating of each of Test Bodies A2, A4-A6, A8-A10, and B3 was performed by X-ray photoelectron spectroscopic analysis (XPS). The apparatus used in the XPS and the analysis conditions were as below.

(XPS Apparatus and XPS Analysis Conditions)

XPS apparatus: “PHI5000 VersaProbe III” made by Ulvac-Phi, Inc.

X-ray source: Al-Kα (monochromatized)

Output: 25 W, 15 kV

Spot diameter: 100 μm

Extraction angle: 45°

Pass energy: 55 eV

Time step: 20 ms

Sweep count: 5

In the XPS, first, with regard to the copper film of each of Test Bodies A2, A4-A6, A8-A10, and B3, an organic film of several nanometers of surface layer was removed by Ar sputtering. Subsequently, O 1s spectra, Cu 2p spectra, and Cu LMM spectra were measured using the above-mentioned conditions. The measurement results for Test Bodies A9, A10, A5, and B3 are shown in FIG. 1 to FIG. 3.

According to the measurement results of the O 1s spectra shown in FIG. 1, with regard to Test Body B3, in which a copper film was formed by vapor deposition without oxygen, the amount of oxygen in the copper film was minute, and the Cu was zerovalent. With regard to Test Bodies A9, A10, A5, it was confirmed that the amount of oxygen in the copper film increased as the amount of oxygen that was introduced increased.

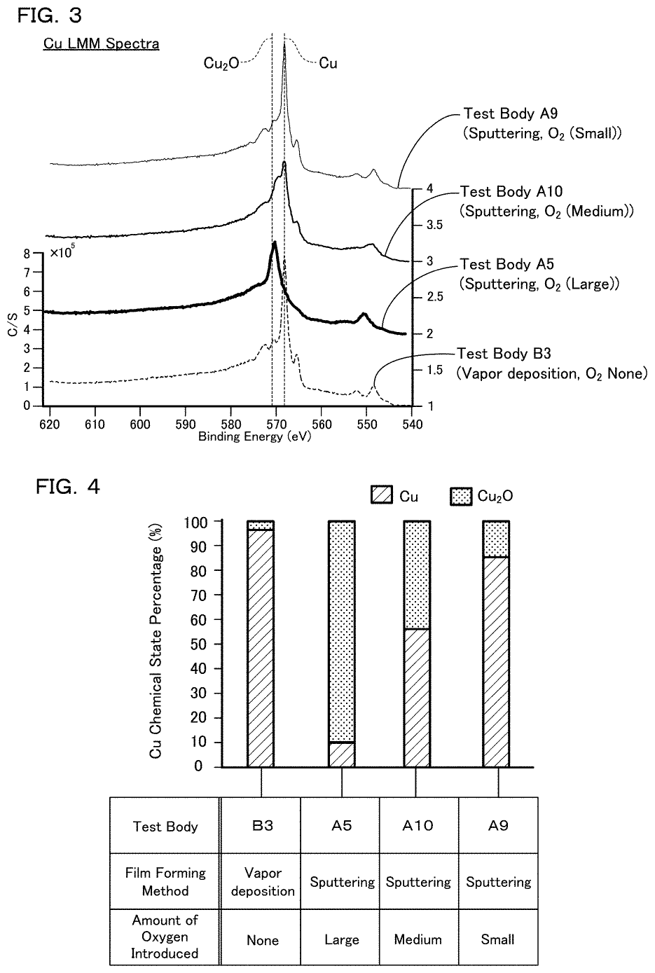

According to the measurement results of the Cu 2p spectra shown in FIG. 2, in every test body, the main peaks were at Cu or Cu₂O, and the proportion of satellite peaks resulting from divalent Cu was small. In addition, according to the measurement results of the Cu LMM spectra shown in FIG. 3: with regard to Test Body A5, in which the amount of oxygen introduced was large, the peak was shifted to univalent Cu; with regard to Test Body A10, in which the amount of oxygen introduced was at the medium level, and Test Body A9, in which the amount of oxygen introduced was small, peaks appeared at both Cu and univalent Cu. Furthermore, with regard to each of Test Bodies A9, A10, A5, and B3, the CuO peak and the Cu and Cu₂O peak were isolated from the measurement results of the Cu 2p spectrum shown in FIG. 2, and the atomic weight ratio between the CuO and the Cu and Cu₂O was calculated from both peak surface areas.

As shown in FIG. 2 and FIG. 3, because it is difficult to isolate the wavelengths of the Cu and Cu₂O peaks, O outside of O contained in CuO was regarded as being bonded with Cu, and the atomic weight ratios of Cu and Cu₂O were calculated from semiquantitative values. The calculation results are shown in the “XPS Analysis Result” column in Table 2 below and in FIG. 4. In addition, with regard to Test Bodies A2, A4, A6, and A8 as well, the atomic weight ratios were calculated likewise and are shown in the same column in Table 2 below.

TABLE 2

| | | | | | XPS Analysis | |
|---|---|---|---|---|---|---|
| Test | | Film | Amount of | Cu Film | Result | |
| Body | Base | Forming | Oxygen | Thickness | (atm %) | |
| Symbol | Material | Method | Introduced | (XRF) | Cu | Cu₂O |
| A2 | PET | Sputtering | Large | 5 nm | 9.3 | 90.7 |
| A4 | | | | 19 nm | 6.6 | 93.4 |
| A5 | | | | 26 nm | 9.7 | 90.3 |
| A6 | | | | 32 nm | 5.0 | 95.0 |
| A8 | | | None | 20 nm | 96.1 | 3.9 |
| A9 | | | Small | 25 nm | 85.6 | 14.4 |
| A10 | | | Medium | 24 nm | 55.8 | 44.2 |
| B3 | PET | Vapor | None | 18 nm | 96.1 | 3.9 |
| | | deposition | | | | |

According to the XPS analysis results shown in Table 2 above, when comparing Test Bodies A2-A6, the amount of oxygen introduced for every one was the same amount: “Large”; and the ratios of the amounts of non-oxide copper in the copper films were the same amount, regardless of the film thickness. On the other hand, when comparing Test Bodies A5, A8-A10, the film thicknesses of the copper films were the same amount and the ratios of the amounts of non-oxide copper in the copper films became large as the amount of oxygen introduced became large. Accordingly, the ratio of the amount of non-oxide copper exhibited a tendency in which the ratio did not depend on the film thickness but did depend on the amount of oxygen introduced during the copper-film formation.

Furthermore, based on the above calculation results, with regard to each of Test Bodies A2, A4-A6, A8-A10, and B3, the atomic weight ratio of the copper oxides (CuO+Cu₂O) and the non-oxide copper (Cu) that constituted the copper film was calculated and the ratio of the copper oxides (CuO+Cu₂O), that is, (CuO+Cu₂O)/(CuO+Cu₂O+Cu), was recorded in the “CuO+Cu₂O Ratio” column in Table 1. Furthermore, the mass amounts of the non-oxide copper in the coatings were calculated from the amounts of Cu, which were the masses of Cu measured by the atomic absorption spectral analysis method described above, and from the atomic weight ratios of the copper oxides and non-oxide copper described above, and the calculation results were recorded in the “Amount of Non-Oxide Copper” column in Table 1 above.

As recorded in the “CuO+Cu₂O Ratio” column in Table 1 above, for every one of Test Bodies A2 and A4-A6, the amount of copper that forms the copper oxide(s) was 90% or more with respect to the amount of Cu (the total amount of the copper, which forms the copper oxide(s), and the non-oxide copper). Furthermore, as recorded in the “Amount of Non-Oxide Copper” column in Table 1 above, with regard to each of Test Bodies A2 and A4-A6, the amount of non-oxide copper was within the range of 0.04 g/m² or less. In addition, with regard to each of the same test bodies, the amount of Cu in the copper film was 0.04 g/m² or more. It is noted that the numerical value recorded in the “Amount of Non-Oxide Copper” column for each of Test Bodies A3, A7, A12-A18 was an evaluation value—not an actual measured value—in which the amount of non-oxide copper was estimated based on the “CuO+Cu₂O Ratio” for Test Body A5 shown in Table 1. Likewise, the numerical value recorded in the “Amount of Non-Oxide Copper” column for each of Test Bodies B1, B2, B4, B5 was an evaluation value—not an actual measured value—in which the amount of non-oxide copper was estimated based on the “CuO+Cu₂O Ratio” for Test Body B3 shown in Table 1.

Continuing, the evaluation of the light transmittance, the insulating property, and the antimicrobial effect for each of the test bodies was performed as below.

(Evaluation of Light Transmittance)

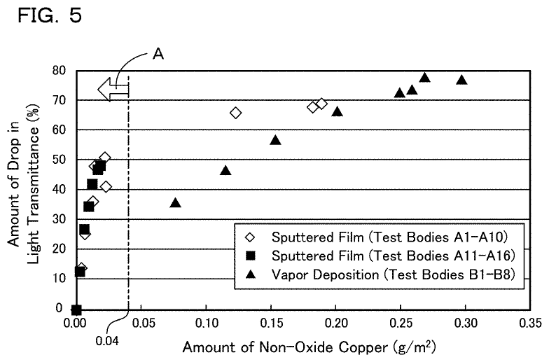

Using a haze meter (“NDH-2000” made by Nippon Denshoku Industries Co., Ltd.) and a method compliant with JIS K7361-1:1997, the total light transmittance of each test body was measured (light source: D65), and the result was recorded in the “Light Transmittance” column in Table 1. In addition, as the amount of drop in light transmittance, the differences between the light transmittance of each of Test Bodies A2-A10 and each of Test Bodies B1-B8 and the light transmittance of Test Body A1, which did not have a copper film, were calculated, and the differences between the light transmittance of each of Test Bodies A12-A17 and the light transmittance of Test Body A11, which did not have a copper film, were calculated, and the results thereof were recorded in the “Amount of Drop in Light Transmittance” column in Table 1 above. In addition, the relationship between the amount of non-oxide copper and the amount of drop in light transmittance is shown in FIG. 5.

As shown in FIG. 5, in the range in which the amount of non-oxide copper is 0.04 g/m² or less, which is indicated by arrow A, the correlation between the amount of non-oxide copper and the amount of drop in light transmittance was remarkable. The correlation was remarkable in the area in which the amount of drop in light transmittance was comparatively low, on the order of 10-60%, that is, in the area in which light transmittance was comparatively high. In this area, the relationship was such that change in the amount of non-oxide copper was sensitively reflected in the change in the amount of drop in light transmittance, and the amount of drop in light transmittance increased (i.e., the light transmittance decreased) as the amount of non-oxide copper was increased. On the other hand, in the range in which the amount of non-oxide copper was greater than 0.04 g/m², changes in the amount of non-oxide copper tended not to be reflected in changes in the amount of drop in light transmittance.

As shown in Table 1, when comparing the light transmittances of Test Body A7 and Test Bodies B5 (No Oxygen Introduced) and B8 (Large Amount of Oxygen Introduced), which all had the same target film thickness, the light transmittance of Test Body A7, which had a copper film composed of a sputtered film, was higher than the light transmittance of each of Test Bodies B5, B8, which had a copper film composed of a vapor-deposited film. In Test Bodies A3-A6 and Test Bodies B1-B4 as well, the light transmittance of each of Test Bodies A3-A6, which had a copper film composed of a sputtered film, was likewise high, as long as it had the same target film thickness.

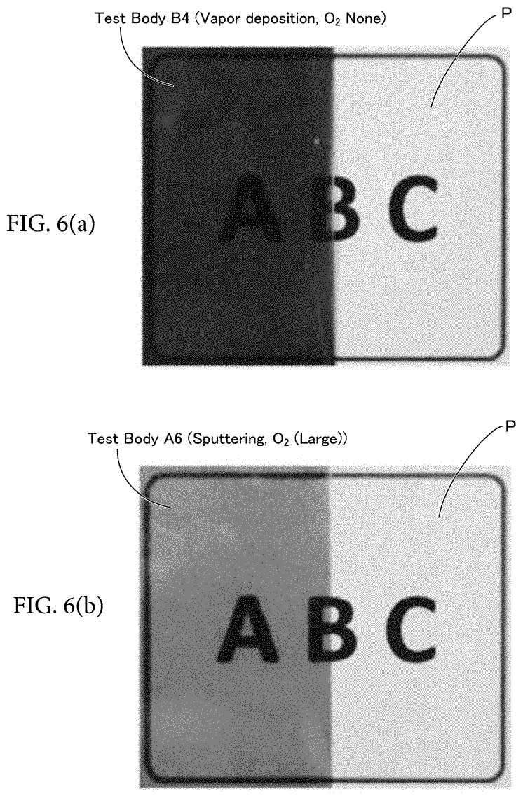

In addition, in the present example, the visibility of printed content when a printed object, which was monochromatically printed using a laser printer, and a test body were overlapped was also evaluated. FIG. 6(a) illustrates the state in which Test Body B4 overlapped a printed object P, and FIG. 6(b) illustrates the state in which Test Body A4 overlapped the printed object P. Symbol “A” was recorded in the “Visibility” column in Table 1 in the situation in which, in the state in which the test body overlapped the printed object P, the printed content was visible without the transmission of light from the rear surface. In addition, symbol “B” was recorded in the situation in which the printed content was visible, as long as light was transmitted from the rear surface. On the other hand, symbol “C” was recorded in the situation in which the printed content was not visible, even if light was transmitted from the rear surface.

As shown in Table 1, in each of Test Bodies A9, B5-B8, the light transmittance was 20% or less, the printed content was not visible even if light was transmitted from the rear surface, and the visibility of the printed object P was unsatisfactory. On the other hand, with regard to each of A1-A7, A11-A18, B1-B3, the light transmittance was greater than 30% and, as illustrated in FIG. 6(a), the printed content was visible without the transmission of light from the rear surface, and therefore visibility was satisfactory. In addition, with regard to each of Test Bodies A8, A10, B4, the light transmittance was greater than 20% and 30% or less, and the printed content was visible, as long as light was transmitted from the rear surface. Furthermore, as shown in FIG. 6(a) and FIG. 6(b), in every one of Test Bodies A2-A7, A10, A12-A18, a copper color, a brass color, or the like were suitably exhibited. In each one, because it was visible in the state in which a copper color was suitably exhibited, the area overlapped by the test body became easy to recognize. Furthermore, with regard to each of Test Bodies A2-A7 and A12-A18, as shown by the arrow A in FIG. 5, by adjusting the non-oxide copper to within the range of 0.04 g/m² or less, the intensity of the hue of the copper color could be adjusted.

(Evaluation of Insulating Property)

Using a low-resistivity meter (“Loresta GP” made by Mitsubishi Analytech Co., Ltd.) and a method compliant with JIS K7194:1995, the surface resistivity of the copper-film surface of each of the test bodies was measured. The measurement results were as recorded in the “Surface Resistivity” column in Table 1. In addition, as the evaluation of the capacitance-type touch panel properties, each test body was placed on a capacitance-type touch-panel monitor, and whether the touch panel responded normally was evaluated. With regard to the evaluating method, the situation in which the touch panel responded normally was evaluated as satisfactory (◯), and the situation in which the touch panel did not respond normally and the situation in which a location other than the touched region responded were evaluated as unsatisfactory (x); the evaluation results were recorded in the “Capacitance-Type Touch Panel Properties” column in Table 1.

As shown in Table 1, the surface resistivity for each of Test Bodies A1-A7, A11-A18 was extremely high and therefore unmeasurable, i.e., O.L. (1×10⁶(Ω/□) or more). Furthermore, the capacitance-type touch panel properties for every one of the same test bodies was satisfactory. In addition, with regard to Test Body A10, surface resistivity was sufficiently high at 988(Ω/□), and the capacitance-type touch panel properties were satisfactory. On the other hand, with regard to each of Test Bodies A8, A9, surface resistivity was low and the capacitance-type touch panel properties were unsatisfactory. In addition, with regard to each of Test Bodies B1-B8 as well, surface resistivity was low and the capacitance-type touch panel properties were unsatisfactory. Thereby, it was surmised that the capacitance-type touch panel properties were satisfactory as long as the surface resistivity was a high value of 950(Ω/□) or more.

(Evaluation of Antimicrobial Efficacy)

The evaluation of the antimicrobial efficacy was performed as follows. First, an antimicrobial-treated test piece, which exhibited a square shape that was 40 mm on a side, was collected from each of Test Bodies A12-A16 and B1-B5. In addition, unprocessed test pieces, each of which exhibited a square shape that was 40 mm on a side, were collected from the resin films prior to the copper films being formed. Using these test pieces, antimicrobial tests were performed using the method stipulated in JIS Z2801:2010. The microbes used in the tests were Staphylococcus aureus and Escherichia coli, and the culture time was set to 24 h.

The antimicrobial-activity value, which indicates the magnitude of the antimicrobial efficacy, was calculated based on the viable-cell count after each test piece was cultured for 24 h, and the calculation result was recorded in the “Antimicrobial-Activity Value” column in Table 1. Antimicrobial-activity value R was calculated specifically using the equation below. It is noted that symbol Ut in the equation below is the average value of the common logarithms of the viable-cell counts after the unprocessed test pieces were cultured for 24 h, and At is the average value of the common logarithms of the viable-cell counts after the antimicrobial-treated test pieces were cultured for 24 h.

R=Ut−At

With regard to the evaluation of the antimicrobial efficacy, the antimicrobial efficacy was determined to be PASS in the situation in which antimicrobial-activity values R for both Staphylococcus aureus and Escherichia coli were 2.0 or more, and the antimicrobial efficacy was determined to be FAIL in the situation in which the antimicrobial-activity value R for at least one of Staphylococcus aureus and Escherichia coli was less than 2.0. As shown in Table 1, with regard to Test Body B1, the antimicrobial-activity value for Escherichia coli was less than 2.0, and therefore was FAIL; however, with regard to each of the other Test Bodies A12-A16 and B2-B5, the antimicrobial-activity value was 2.0 or more, and therefore was PASS. It is noted that, with regard to each of Test Bodies A2-A6, the composition of the resin film differed from that of Test Bodies A12-A16, but the composition of the copper film was the same, and the copper film contained an amount of Cu of 0.04 g/m² or more. Consequently, for each of Test Bodies A2-A10, A17, and Alb as well, it was surmised that an antimicrobial-activity value equivalent to that of Test Bodies A12-A16 would be obtained.

The effects and efficacies of the antimicrobial sheets of the present examples are described in detail below.

In the antimicrobial sheets of the present examples, as in each of the above-mentioned Test Bodies A2-A7 and A12-A18, the copper film contains 0.04 g/m² or less of the non-oxide copper. When content of the non-oxide copper is in the range of 0.04 g/m² or less, there is a correlation between the non-oxide copper content and the light transmittance of the antimicrobial sheet and, in the area in which the amount of non-oxide copper is small, there is a tendency for the light transmittance to change greatly relative to change in the amount of non-oxide copper. Consequently, by adjusting the non-oxide copper content to be within the above-mentioned range, the light transmittance can be easily adjusted while maintaining the light transmittance to the extent that the display contents of the interface can be easily differentiated when the antimicrobial sheet is used on an interface.

In addition, the antimicrobial sheet is composed of copper oxide(s) and non-oxide copper and is in a state in which it is tinged with copper color or brass color. Furthermore, by adjusting the non-oxide copper included in the copper film to within the range of 0.04 g/m² or less, the intensity of the hue of the copper color can be adjusted. For example, by setting the antimicrobial sheet to the state suitably tinged with copper color, it becomes easy to recognize that the antimicrobial sheet is a sheet 1 having an antimicrobial effect; consequently, it is also possible to obtain a sense of security that the propagation of microbes is inhibited on the part where the antimicrobial sheet is provided.

In addition, because antimicrobial metallic thin films of existing antimicrobial films are composed of a metal such as copper, silver, and alloys thereof, which have high conductivity, it is problematic to use them in capacitance-type touch sensors or the like that are used in capacitance-type touch panels, various operation panels, and the like, which are often used in the touch panels of smart phones, and the like. In contrast, with regard to the antimicrobial sheets of the present examples, as in each of the above-mentioned Test Bodies A2-A7 and A12-A18, because the antimicrobial effect is exhibited by the copper film affixed to at least one side of the resin film and because the conductivity of the copper oxide(s) that constitute(s) the copper film is low, it is possible to use the antimicrobial sheets on a capacitance-type touch panel, touch sensor, or the like.

In addition, in the present examples, the copper film is composed of a sputtered film that contains copper oxide(s) and non-oxide copper. Thereby, because the copper film can be made more finely than in the situation in which the copper film is composed of a vapor-deposited film, the film thickness can be made thin without reducing the copper content. In addition, because thin films composed of copper oxide(s) transmits visible light, in particular long-wavelength light, it has high transmittance. As a result, the light transmittance can be increased while maintaining the antimicrobial effect. In addition, a copper film containing the desired amount of non-oxide copper(s) can be formed easily.

In addition, in the present examples, the sum total of the content of the copper that forms the copper oxide(s) and the content of the non-oxide copper is 0.04 g/m² or more. Thereby, because the copper film formed on the resin film exhibits sufficient antimicrobial effect, the antimicrobial effect of the antimicrobial sheet can be ensured.

In addition, in the present examples, a resin film that is transparent to visible light is used as the resin film. The resin film preferably contains one or two or more resins from among polyester, polyolefin, polycarbonate, polyurethane, polyvinyl chloride, and silicone; in the present examples, the resin film is composed of polyethylene terephthalate contained in a polyester. Because the above-mentioned resin film has a high refractive index, the interface reflectance of the above-mentioned copper film, which has a high refractive index, can be reduced, and thereby the transmittance of visible light of the antimicrobial sheet can be further improved. In addition, because the heat resistance of the above-mentioned resin is high, it is possible to curtail deterioration of the resin film when sputtering is performed in the process of manufacturing the antimicrobial sheet.

In addition, the thickness of the resin film can be set to, for example, 5-250 μm and, in the present example, is set to 50 μm or 25 μm. Thereby, handling of the resin film in the manufacturing process is easy, and a decrease in the transmittance of visible light tends not to be incurred.

In addition, the surface resistivity of the antimicrobial sheet can be set to, for example, 950Ω/□ or more and, in the present examples, is set to 988Ω/□ or more. Thereby, because the surface resistance of the antimicrobial sheet becomes sufficiently high, in the situation in which a capacitance-type touch panel is covered by the antimicrobial sheet, the touch panel can operate normally through the antimicrobial sheet; in the situation in which the touch sensor is covered by the antimicrobial sheet, the touch sensor can be actuated normally through the antimicrobial sheet. For this reason, it is an antimicrobial sheet that is suitable to be used by covering a capacitance-type touch panel, touch sensor, or the like.

As described above, according to the present examples, an antimicrobial sheet can be provided in which the light transmittance can be adjusted easily. The antimicrobial sheets of the present examples can be used by covering the interface of an electronic device, such as a keyboard, an operation panel, a touch panel, or the like, by covering a printed object, or by covering an indoor wall surface, furniture, or the like.

1. An antimicrobial sheet comprising:
a resin film; and
a copper film, which is formed on at least one side of the resin film and contains one or more copper oxides and a non-oxide copper;
wherein the content of the non-oxide copper in the copper film is less than the content of the copper that forms the copper oxide(s) and is 0.04 g/m² or less.

2. The antimicrobial sheet according to claim 1, wherein the copper film is composed of a sputtered film that contains the copper oxide(s) and the non-oxide copper.

3. The antimicrobial sheet according to claim 1, wherein the sum total of the content of the copper, which forms the copper oxide(s), and the content of the non-oxide copper is 0.04 g/m² or more.

4. The antimicrobial sheet according to claim 1, wherein the resin film contains one or two or more resins selected from the group consisting of polyester, polyolefin, polycarbonate, polyurethane, polyvinyl chloride, and silicone.

5. The antimicrobial sheet according to claim 1, wherein the thickness of the resin film is 5-250 μm.

6. The antimicrobial sheet according to claim 1, wherein the surface resistivity is 950Ω/□ or more.

7. A method of manufacturing the antimicrobial sheet according to claim 1, wherein the copper film is formed on the resin film by sputtering, in a gas-mixture atmosphere containing an inert gas and oxygen gas, while controlling the amount of the oxygen gas that is introduced.

8. The antimicrobial sheet according to claim 3, wherein the copper film is composed of a sputtered film that contains the copper oxide(s) and the non-oxide copper.

9. The antimicrobial sheet according to claim 8, wherein in the copper film the sum total of the content of the copper, which forms the copper oxide(s), and the content of the non-oxide copper is 0.04 g/m² or more.

10. The antimicrobial sheet according to claim 9, wherein the resin film contains one or two or more resins selected from the group consisting of polyester, polyolefin, polycarbonate, polyurethane, polyvinyl chloride, and silicone.

11. The antimicrobial sheet according to claim 10, wherein the thickness of the resin film is 5-250 μm.

12. The antimicrobial sheet according to claim 11, wherein the surface resistivity is 950Ω/□ or more.

13. The antimicrobial sheet according to claim 12, further comprising an adhesive layer on a side of the resin film that is opposite of the copper film.

14. The antimicrobial sheet according to claim 13, wherein the content of the non-oxide copper in the copper film is 0.02 g/m² or less.

15. The antimicrobial sheet according to claim 14, wherein the ratio of the content of copper that forms the copper oxide(s) relative to the total amount of Cu in the copper film is 85% or more.

16. The antimicrobial sheet according to claim 15, wherein the resin film is composed of polyethylene terephthalate, urethane or polyethylene.

17. The antimicrobial sheet according to claim 16, wherein the non-oxide copper is zerovalent copper and the copper oxide(s) is (are) CuO and/or Cu₂O.

18. The antimicrobial sheet according to claim 17, wherein the surface resistivity of the copper film is 1×10⁶Ω/□ or more.

19. The antimicrobial sheet according to claim 1, wherein the surface resistivity of the copper film is 1×10⁶Ω/□ or more.

20. The antimicrobial sheet according to claim 1, wherein the non-oxide copper is zerovalent copper and the copper oxide(s) is (are) CuO and/or Cu₂O.
